(19) United States
(12) Patent Application Publication
(10) Pub. No.: US 2016/0380605 A1
(43) Pub. Date: Dec. 29, 2016

(54) SAW DEVICE MANUFACTURING METHOD

(71) Applicant: DISCO CORPORATION, Tokyo (JP)

(72) Inventors: Hirokazu Matsumoto, Tokyo (JP); Jun Abatake, Tokyo (JP)

(21) Appl. No.: 15/188,418

(22) Filed: Jun. 21, 2016

(30) Foreign Application Priority Data
Jun. 24, 2015 (JP) 2015-127077

(51) Int. Cl. H03H 3/08; B23K 26/53; H03H 9/145; B23K 26/402; B23K 26/06; B23K 26/00; B23K 26/364

(52) U.S. Cl. CPC H03H 3/08; B23K 26/0057; B23K 26/53; B23K 26/364; B23K 26/402; B23K 26/0006; B23K 26/0619; H03H 9/14544; B23K 2203/30

(57) ABSTRACT

A SAW device wafer has a crystal substrate having a front side partitioned into a plurality of regions by a plurality of crossing division lines, a pair of comblike electrodes formed in each region defined on the front side of the crystal substrate by the division lines, and a cover layer formed of resin for covering the whole of the front side of the crystal substrate. The SAW device is manufactured by forming a laser processed groove on the cover layer along each division line, the laser processed groove having a depth not reaching the crystal substrate, forming a modified layer inside the crystal substrate along each division line, and applying an external force to the SAW device wafer, thereby dividing the SAW device wafer along each division line to obtain the plural SAW devices.

### BACKGROUND OF THE INVENTION

Field of the Invention

The present invention relates to a manufacturing method for a SAW (Surface Acoustic Wave) device having a pair of comblike electrodes on the front side.

Description of the Related Art

A SAW device using SAW (Surface Acoustic Wave) is incorporated in most of wireless communication equipment such as a mobile phone. For example, the SAW device includes a crystal substrate formed of a piezoelectric material such as quartz (SiO₂) and a pair of comblike electrodes (IDT: Inter Digital Transducer) formed on the front side of the crystal substrate. This SAW device can transmit only an electrical signal having a frequency determined by the kind of the piezoelectric material, the spacing between the two electrodes, etc.

In manufacturing the SAW device mentioned above, a plurality of division lines are set on the front side of a crystal substrate to thereby partition the front side of the crystal substrate into a plurality of regions, and a pair of comblike electrodes are provided in each region defined on the front side of the crystal substrate by the division lines. Thereafter, a cover layer of resin is formed on the front side of the crystal substrate to thereby obtain a SAW device wafer. This SAW device wafer is divided (cut) along each division line by using a cutting blade, for example, to obtain a plurality of SAW devices (see Japanese Patent Laid-open Nos. 2005-252335 and 2010-56833, for example).

### SUMMARY OF THE INVENTION

However, when the SAW device wafer including the cover layer formed of resin is divided by using the cutting blade, the cover layer may be chipped to cause an easy reduction in quality of each SAW device.

It is therefore an object of the present invention to provide a SAW device manufacturing method which can suppress a reduction in quality of each SAW device.

In accordance with a first aspect of the present invention, there is provided a SAW device manufacturing method for dividing a SAW device wafer to manufacture a plurality of SAW devices, the SAW device wafer including a crystal substrate having a front side partitioned into a plurality of regions by a plurality of crossing division lines, a pair of comblike electrodes formed in each region defined on the front side of the crystal substrate by the division lines, and a cover layer formed of resin for covering the whole of the front side of the crystal substrate. The SAW device manufacturing method includes: a laser processed groove forming step of applying a first laser beam to the cover layer along each division line, the first laser beam having an absorption wavelength to the resin forming the cover layer, thereby forming a laser processed groove on the cover layer along each division line, the laser processed groove having a depth not reaching the crystal substrate; a modified layer forming step of applying a second laser beam to the crystal substrate from a back side thereof along each division line after performing the laser processed groove forming step, the second laser beam having a transmission wavelength to the crystal substrate, in a condition where a focal point of the second laser beam is set inside the crystal substrate, thereby forming a modified layer inside the crystal substrate along each division line; and a dividing step of applying an external force to the SAW device wafer after performing the modified layer forming step, thereby dividing the SAW device wafer along each division line to obtain the plurality of SAW devices.

In accordance with a second aspect of the present invention, there is provided a SAW device manufacturing method for dividing a SAW device wafer to manufacture a plurality of SAW devices, the SAW device wafer including a crystal substrate having a front side partitioned into a plurality of regions by a plurality of crossing division lines, a pair of comblike electrodes formed in each region defined on the front side of the crystal substrate by the division lines, and a cover layer formed of resin for covering the whole of the front side of the crystal substrate. The SAW device manufacturing method includes: a modified layer forming step of applying a first laser beam to the crystal substrate from a back side thereof along each division line, the first laser beam having a transmission wavelength to the crystal substrate, in a condition where a focal point of the first laser beam is set inside the crystal substrate, thereby forming a modified layer inside the crystal substrate along each division line; a laser processed groove forming step of applying a second laser beam to the cover layer along each division line after performing the modified layer forming step, the second laser beam having an absorption wavelength to the resin forming the cover layer, thereby forming a laser processed groove on the cover layer along each division line, the laser processed groove having a depth not reaching the crystal substrate; and a dividing step of applying an external force to the SAW device wafer after performing the laser processed groove forming step, thereby dividing the SAW device wafer along each division line to obtain the plurality of SAW devices.

In the first aspect or the second aspect of the present invention, the cover layer may include a plurality of resin layers.

In the SAW device manufacturing method according to the first aspect or the second aspect of the present invention, the laser processed groove is formed on the cover layer along each division line, and the modified layer is formed inside the crystal substrate along each division line. Thereafter, an external force is applied to the SAW device wafer to thereby divide it into the plural SAW devices. Accordingly, as compared with the case of dividing (cutting) the SAW device wafer by using a cutting blade, the occurrence of chipping in the cover layer can be reduced. Thusly, according to the first aspect or the second aspect of the present invention, it is possible to provide a SAW device manufacturing method which can suppress a reduction in quality of each SAW device.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a schematic perspective view showing the configuration of a SAW device wafer according to a preferred embodiment of the present invention;

FIG. 1B is an enlarged perspective view of a part of the front side of the SAW device wafer shown in FIG. 1A;

FIG. 1C is an enlarged sectional view of a part of the SAW device wafer shown in FIG. 1A;

FIG. 2 is a schematic perspective view showing the configuration of a laser processing apparatus for use in carrying out the present invention;

FIG. 3A is a partially sectional side view schematically showing a laser processed groove forming step according to this preferred embodiment;

FIG. 3B is a partially sectional side view schematically showing a modified layer forming step according to this preferred embodiment;

FIG. 4 is a partially sectional side view schematically showing a dividing step according to this preferred embodiment;

FIG. 5 is a schematic sectional view showing the configuration of a SAW device wafer according to a modification; and

FIGS. 6A and 6B are partially sectional side views schematically showing a dividing step according to another modification.

### DETAILED DESCRIPTION OF THE PREFERRED EMBODIMENTS

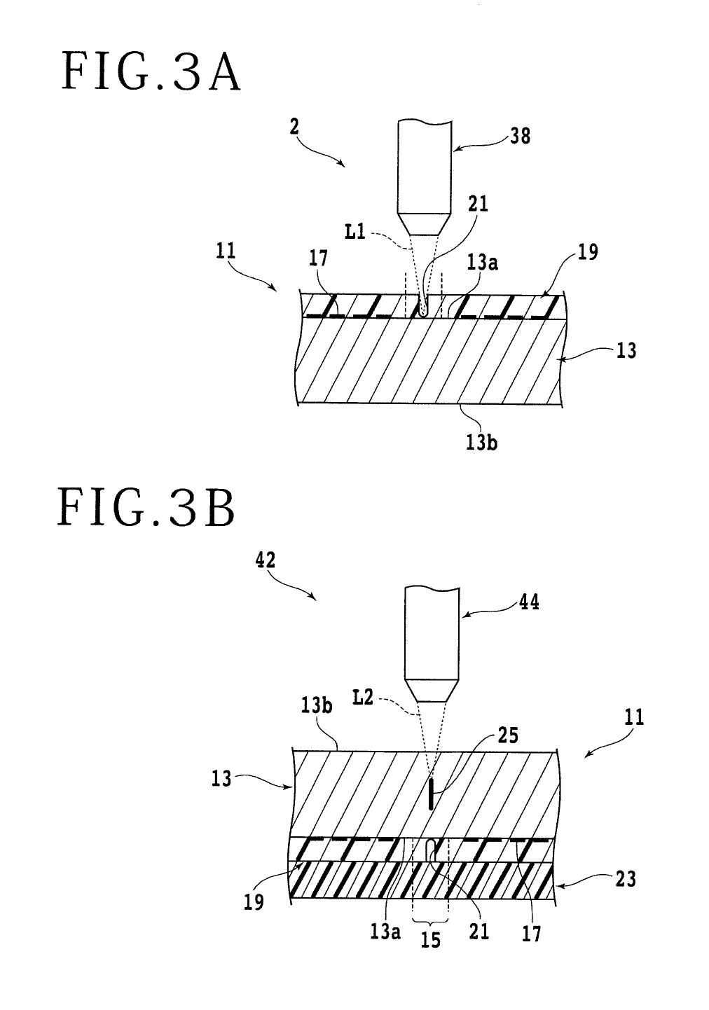

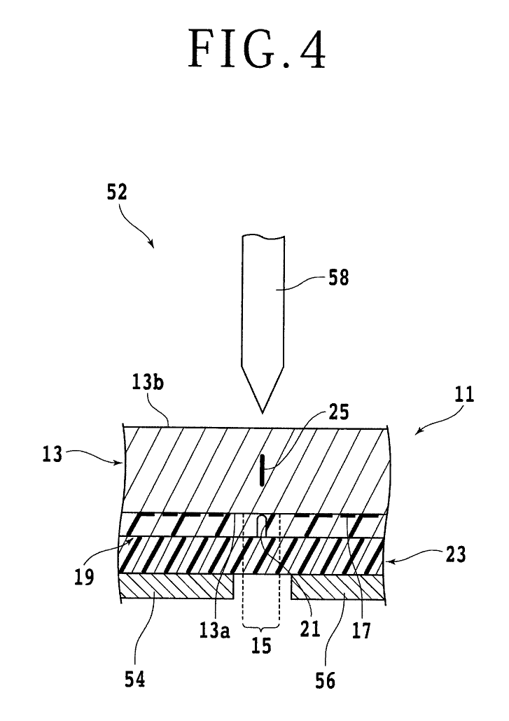

A preferred embodiment of the present invention will now be described with reference to the attached drawings. The SAW (Surface Acoustic Wave) device manufacturing method according to this preferred embodiment includes a laser processed groove forming step (see FIG. 3A), a modified layer forming step (see FIG. 3B), and a dividing step (see FIG. 4). In the laser processed groove forming step, a laser beam is applied to a cover layer constituting a SAW device wafer, thereby forming a laser processed groove along each division line (street). In the modified layer forming step, a laser beam is applied to a crystal substrate constituting the SAW device wafer, thereby forming a modified layer along each division line. In the dividing step, an external force is applied to the SAW device wafer, thereby dividing the SAW device wafer along each division line to obtain a plurality of SAW devices. The SAW device manufacturing method according to this preferred embodiment will now be described in more detail.

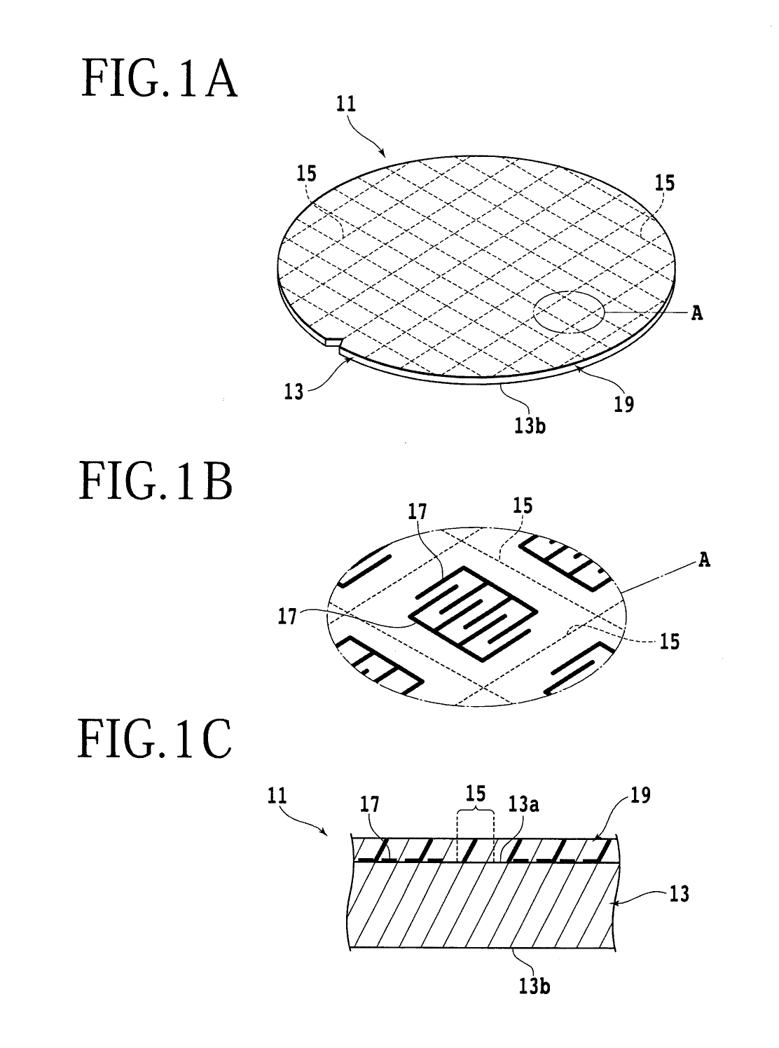

FIG. 1A is a schematic perspective view showing the configuration of a SAW device wafer 11 to be used in this preferred embodiment. FIG. 1B is an enlarged perspective view of a part (encircled region A in FIG. 1A) of the front side of the SAW device wafer 11. FIG. 1C is an enlarged sectional view of a part of the SAW device wafer 11. As shown in FIGS. 1A, 1B, and 1C, the SAW device wafer 11 includes a circular crystal substrate 13 formed of a piezoelectric material such as quartz (SiO₂), lithium niobate (LiNbO₃), and lithium tantalate (LiTaO₃). The crystal substrate 13 has a front side 13a and a back side 13b. The front side 13a of the crystal substrate 13 is partitioned into a plurality of regions by a plurality of crossing division lines (streets) 15. In each region, a pair of comblike electrodes (IDT: Inter Digital Transducer) 17 meshing each other are formed. A cover layer 19 is formed on the front side 13a of the crystal substrate 13. The cover layer 19 is formed of resin such as epoxy resin, polyimide resin, and phenol resin. The whole of the front side 13a is covered with this resin forming the cover layer 19. A partial space (gap) or the like may be formed between the crystal substrate 13 and the cover layer 19. By dividing this SAW device wafer 11 along the plural division lines 15, a plurality of SAW devices can be manufactured.

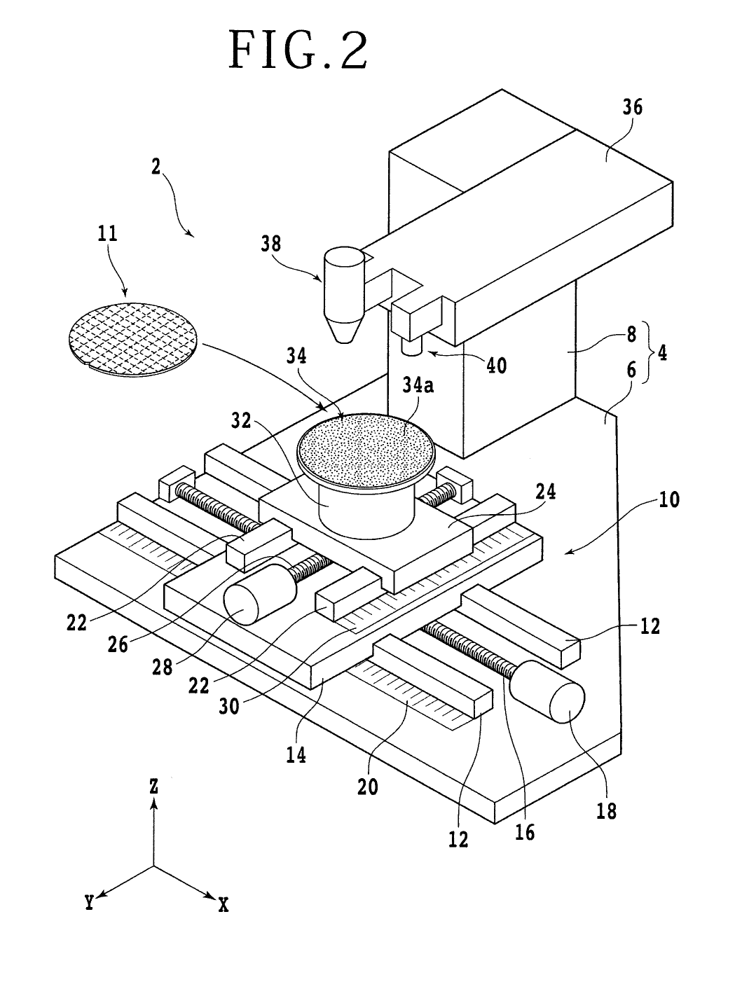

In the SAW device manufacturing method according to this preferred embodiment, a laser processed groove forming step is performed in such a manner that a laser beam is applied to the cover layer 19 to thereby form a laser processed groove on the cover layer 19 along each division line 15. FIG. 2 is a schematic perspective view showing the configuration of a laser processing apparatus 2 for use in performing the laser processed groove forming step. FIG. 3A is a partially sectional side view schematically showing the laser processed groove forming step. As shown in FIG. 2, the laser processing apparatus 2 includes a base unit 4 for supporting various components. The base unit 4 includes a horizontal base portion 6 and a column portion 8 vertically extending from the rear end of the base portion 6. A chuck table moving mechanism 10 is provided on the upper surface of the base portion 6 at the center thereof. The chuck table moving mechanism 10 includes a pair of parallel X guide rails 12 provided on the upper surface of the base portion 6 so as to extend in an X direction (feeding direction) shown by an arrow X in FIG. 2. An X moving table 14 is slidably mounted on the X guide rails 12. A nut portion (not shown) is provided on the back side (lower surface) of the X moving table 14, and an X ball screw 16 parallel to the X guide rails 12 is threadedly engaged with this nut portion.

An X pulse motor 18 is connected to one end of the X ball screw 16. When the X ball screw 16 is rotated by the X pulse motor 18, the X moving table 14 is moved along the X guide rails 12 in the X direction. An X scale 20 for detecting the X position of the X moving table 14 in the X direction is provided adjacent to one of the guide rails 12. A pair of parallel Y guide rails 22 are provided on the front side (upper surface) of the X moving table 14 so as to extend in a Y direction (indexing direction) shown by an arrow Y in FIG. 2. A Y moving table 24 is slidably mounted on the Y guide rails 22. A nut portion (not shown) is provided on the back side (lower surface) of the Y moving table 24, and a Y ball screw 26 parallel to the Y guide rails 22 is threadedly engaged with this nut portion. A Y pulse motor 28 is connected to one end of the Y ball screw 26. When the Y ball screw 26 is rotated by the Y pulse motor 28, the Y moving table 24 is moved along the Y guide rails 22 in the Y direction. A Y scale 30 for detecting the Y position of the Y moving table 24 in the Y direction is provided adjacent to one of the Y guide rails 22.

A table base 32 is provided on the front side (upper surface) of the Y moving table 24. A chuck table 34 for holding the SAW device wafer 11 under suction is provided at the upper portion of the table base 32. The chuck table 34 is connected to a rotational drive source (not shown) such as a motor, so that the chuck table 34 is rotatable about its axis extending in a Z direction (vertical direction) by the rotational drive source. With the above configuration, the chuck table 34 is fed in the X direction by operating the chuck table moving mechanism 10 to move the X moving table 14 in the X direction. Further, the chuck table 34 is indexed in the Y direction by operating the chuck table moving mechanism 10 to move the Y moving table 24 in the Y direction. The chuck table 34 has an upper surface as a holding surface 34a for holding the SAW device wafer 11 under suction. The holding surface 34a is connected to a vacuum source (not shown) through a suction passage (not shown) or the like formed inside the chuck table 34 and the table base 32.

A support arm 36 is provided at the upper portion of the column portion 8 so as to extend frontward. A laser processing unit 38 is provided at the front end of the support arm 36. The laser processing unit 38 functions to downward apply a laser beam oscillated in the form of pulses from a laser oscillator (not shown). Further, an imaging unit 40 for imaging the SAW device wafer 11 is also provided at the front end of the support arm 36 at a position adjacent to the laser processing unit 38. For example, when the laser beam is applied from the laser processing unit 38 to the SAW device wafer 11 held on the chuck table 34 and the chuck table 34 is fed in the X direction, the SAW device wafer 11 can be laser-processed in the X direction. The laser oscillator for the laser processing unit 38 is adapted to oscillate a laser beam having a wavelength (absorption wavelength) at which light can be easily absorbed by the resin forming the cover layer 19.

In performing the laser processed groove forming step, the SAW device wafer 11 is first placed on the chuck table 34 in the condition where the back side of the SAW device wafer 11 (the back side 13b of the crystal substrate 13) is opposed to the holding surface 34a of the chuck table 34. Thereafter, a vacuum generated from the vacuum source is applied to the holding surface 34a of the chuck table 34. Accordingly, the SAW device wafer 11 is held on the holding surface 34a of the chuck table 34 under suction in the condition where the front side of the SAW device wafer 11 (the cover layer 19 of the SAW device wafer 11) is exposed upward. Thereafter, the chuck table 34 is moved and rotated to set the laser processing unit 38 directly above a processing start position (e.g., one end of a predetermined one of the division lines 15 as a target region to be processed). Thereafter, as shown in FIG. 3A, a laser beam L1 having a wavelength at which light can be easily absorbed by the cover layer 19 (resin) is applied from the laser processing unit 38 to the cover layer 19, and at the same time the chuck table 34 is moved in the X direction parallel to the predetermined division line 15. That is, the laser beam L1 having an absorption wavelength to the cover layer 19 (resin) is applied to the cover layer 19 along the predetermined division line 15. As a result, a part of the cover layer 19 is ablated along the predetermined division line 15 by the laser beam L1 to thereby form a laser processed groove 21 on the cover layer 19 along the predetermined division line 15.

For example, in the case of forming the laser processed groove 21 on the cover layer 19 having a thickness of 1 μm to 100 μm, the laser processing conditions may be set as follows:

Wavelength: 355 nm

Repetition frequency: 200 kHz

Power: 1.4 W

Work feed speed: 250 mm/s

Number of passes: 1

The other conditions including the power density and the position of the focal point of the laser beam L1 may be adjusted in such a range that the laser processed groove 21 can be formed so as to have a depth not reaching the crystal substrate 13. However, if the laser processed groove 21 is too shallow, there arises a problem such that the cover layer 19 may be easily chipped in the subsequent dividing step. Accordingly, the processing conditions are preferably adjusted so that the depth of the laser processed groove 21 becomes 10% or more of the thickness of the cover layer 19. The above-mentioned procedure of the laser processing is repeated for all of the other division lines 15 to thereby form similar laser processed grooves 21 along all of the other division lines 15. In this manner, the laser processed groove forming step is finished.

After performing the laser processed groove forming step, a modified layer forming step is performed in such a manner that a laser beam is applied to the crystal substrate 13 to thereby form a modified layer inside the crystal substrate 13 along each division line 15. FIG. 3B is a partially sectional side view schematically showing the modified layer forming step. Prior to performing the modified layer forming step, a filmlike protective member 23 is preferably attached to the front side of the SAW device wafer 11 (the cover layer 19). The modified layer forming step is performed by using a laser processing apparatus 42 shown in FIG. 3B. The basic configuration of the laser processing apparatus 42 is the same as that of the laser processing apparatus 2 used in performing the laser processed groove forming step. However, a laser oscillator (not shown) for a laser processing unit 44 included in the laser processing apparatus 42 is adapted to oscillate a laser beam L2 having a wavelength (transmission wavelength) at which light cannot be easily absorbed by the crystal substrate 13.

In performing the modified layer forming step, the SAW device wafer 11 is first placed on a chuck table (not shown) included in the laser processing apparatus 42 in the condition where the protective member 23 attached to the front side of the SAW device wafer 11 is opposed to the upper surface (holding surface) of this chuck table. Thereafter, a vacuum generated from a vacuum source (not shown) is applied to the holding surface of this chuck table. As a result, the SAW device wafer 11 is held through the protective member 23 on the holding surface of this chuck table under suction in the condition where the back side of the SAW device wafer 11 (the back side 13b of the crystal substrate 13) is exposed upward. Thereafter, this chuck table is moved and rotated to set the laser processing unit 44 directly above a processing start position (e.g., one end of a predetermined one of the division lines 15 as a target region to be processed). Thereafter, as shown in FIG. 3B, a laser beam L2 having a wavelength at which light cannot be easily absorbed by the crystal substrate 13 is applied from the laser processing unit 44 to the crystal substrate 13, and at the same time the chuck table is moved in the X direction parallel to the predetermined division line 15. That is, the laser beam L2 having a wavelength at which light cannot be easily absorbed by the crystal substrate 13 is applied to the crystal substrate 13 from the back side 13b thereof along the predetermined division line 15. The focal point of the laser beam L2 is preliminarily set inside the crystal substrate 13. As a result, the inside of the crystal substrate 13 is modified along the predetermined division line 15 by the laser beam L2 to thereby form a modified layer 25 inside the crystal substrate 13 along the predetermined division line 15.

For example, in the case of forming the modified layer 25 inside the crystal substrate 13 having a thickness of 10 μm to 300 μm, the crystal substrate 13 being formed of lithium tantalate (LiTaO₃), the laser processing conditions may be set as follows:

Wavelength: 1030 nm

Repetition frequency: 100 kHz

Power: 5 W

Work feed speed: 360 mm/s

Number of passes: 2

The other conditions including the power density of the laser beam L2 may be adjusted in such a range that the modified layer 25 can be properly formed inside the crystal substrate 13. The above-mentioned procedure of the laser processing is repeated for all of the other division lines 15 to thereby form similar modified layers 25 along all of the other division lines 15. In this manner, the modified layer forming step is finished.

After performing the modified layer forming step, a dividing step is performed in such a manner that an external force is applied to the SAW device wafer 11 to thereby divide the SAW device wafer 11 along each division line 15, thus obtaining a plurality of SAW devices. FIG. 4 is a partially sectional side view schematically showing the dividing step. For example, the dividing step is performed by using a breaking apparatus 52 shown in FIG. 4. The breaking apparatus 52 includes a pair of support plates 54 and 56 horizontally arranged with a gap defined therebetween for supporting the SAW device wafer 11 and a push blade 58 located above the support plates 54 and 56. The push blade 58 is located at a position corresponding to the gap defined between the support plate 54 and the support plate 56. The push blade 58 is adapted to be vertically moved (raised and lowered) by a push mechanism (not shown).

In performing the dividing step, the SAW device wafer 11 is placed on the support plates 54 and 56 in the condition where the protective member 23 attached to the front side of the SAW device wafer 11 is opposed to the support plates 54 and 56. Thereafter, the SAW device wafer 11 is moved with respect to the support plates 54 and 56 to set a predetermined one of the division lines 15 in alignment with the gap between the support plates 54 and 56 in the vertical direction. That is, as shown in FIG. 4, the predetermined division line 15 is set directly below the push blade 58. Thereafter, the push blade 58 is lowered to push the SAW device wafer 11 from the back side thereof (the back side 13b of the crystal substrate 13). The SAW device wafer 11 is supported from the lower side thereof by the support plates 54 and 56 on both sides of the predetermined division line 15. Accordingly, when the SAW device wafer 11 is pushed by the push blade 58, a stress (external force) is applied to a portion in the vicinity of the predetermined division line 15, so that the crystal substrate 13 (the SAW device wafer 11) is divided at the modified layer 25 as a break start point corresponding to the predetermined division line 15. Thereafter, this procedure of the dividing step is repeated for all of the other division lines 15 to thereby similarly divide the SAW device wafer 11 along all of the other division lines 15, thus obtaining a plurality of SAW devices. In this manner, the dividing step is finished.

As described above, in the SAW device manufacturing method according to this preferred embodiment, the laser processed groove 21 is first formed on the cover layer 19 along each division line 15, and the modified layer 25 is next formed inside the crystal substrate 13 along each division line 15. Thereafter, an external force is applied to the SAW device wafer 11 to thereby divide the SAW device wafer 11 along each division line 15, thus obtaining a plurality of SAW devices. Accordingly, as compared with the case of dividing (cutting) the SAW device wafer 11 by using a cutting blade, the occurrence of chipping in the cover layer 19 can be reduced. That is, a reduction in quality of each SAW device can be suppressed.

The present invention is not limited to the above preferred embodiment, but various modifications may be made. For example, while the modified layer forming step is performed after performing the laser processed groove forming step in this preferred embodiment, the laser processed groove forming step may be performed after performing the modified layer forming step.

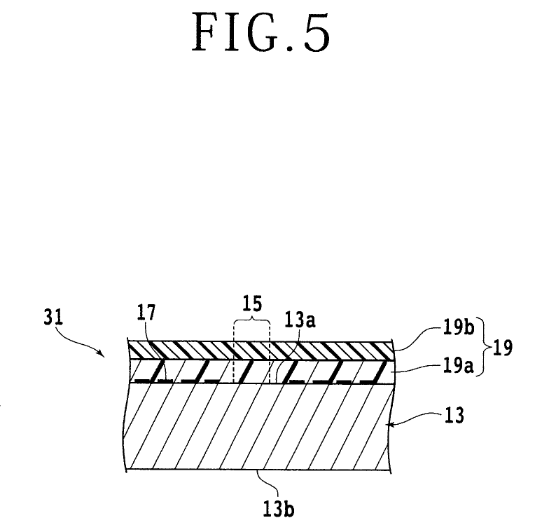

Further, the cover layer of the SAW device wafer in the present invention may be composed of a plurality of resin layers. FIG. 5 is a schematic sectional view showing the configuration of a SAW device wafer 31 according to a modification. In FIG. 5, substantially the same parts as those of the SAW device wafer 11 according to the above preferred embodiment are denoted by the same reference symbols. As shown in FIG. 5, the SAW device wafer 31 according to this modification has a cover layer 19 composed of two resin layers 19a and 19b. Also in this case, a plurality of SAW devices can be manufactured by performing processing steps similar to those of the above preferred embodiment. The material, thickness, etc. of the plural resin layers (resin layers 19a and 19b) constituting the cover layer 19 may be arbitrarily set and modified.

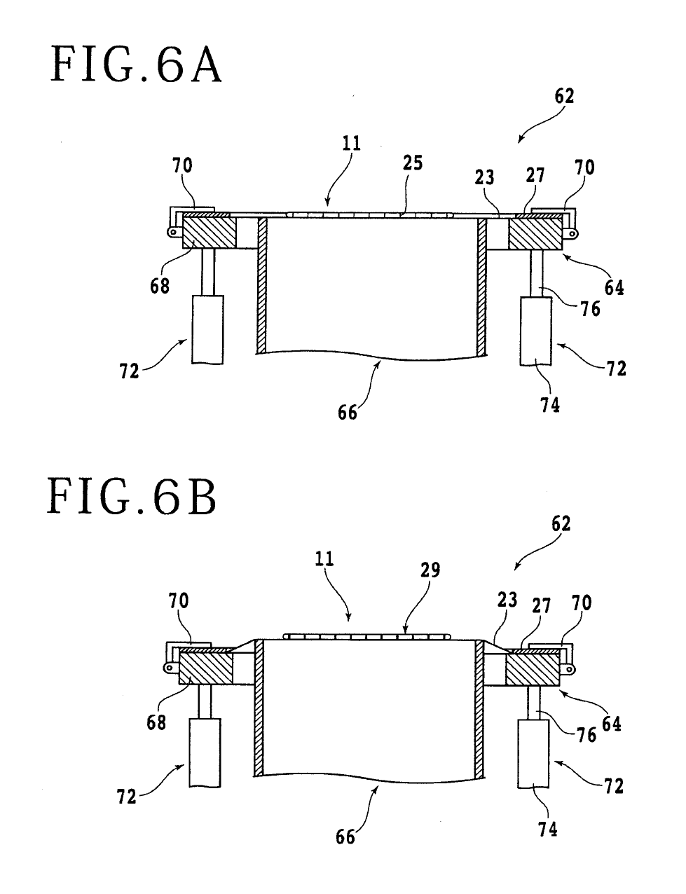

Further, while the breaking apparatus 52 is used to divide the SAW device wafer 11 into the plural SAW devices in the dividing step according to the above preferred embodiment, any other methods may be adopted to divide the SAW device wafer 11. FIGS. 6A and 6B are partially sectional side views schematically showing a dividing step according to another modification. The dividing step according to this modification is performed by using an expanding apparatus 62 shown in FIGS. 6A and 6B. In this case, as shown in FIGS. 6A and 6B, a dicing tape having a diameter larger than that of the SAW device wafer 11 is used as the protective member 23, and an annular frame 27 is preliminarily fixed to the peripheral portion of the protective member 23.

The expanding apparatus 62 includes a support structure 64 for supporting the SAW device wafer 11 and a cylindrical expansion drum 66 for expanding the protective member 23 attached to the SAW device wafer 11. The inner diameter of the expansion drum 66 is larger than the diameter of the SAW device wafer 11, and the outer diameter of the expansion drum 66 is smaller than the inner diameter of the frame 27. The support structure 64 includes a frame support table 68 for supporting the frame 27. The frame support table 68 has an upper surface as a support surface for supporting the frame 27. A plurality of clamps 70 for fixing the frame 27 are provided on the outer circumference of the frame support table 68. A plurality of vertically moving mechanisms 72 are provided below the support structure 64. Each vertically moving mechanism 72 includes a cylinder case 74 fixed at its lower end to a base (not shown) and a piston rod 76 inserted in the cylinder case 74 from its upper end. The lower surface of the frame support table 68 is fixed to the upper end of the piston rod 76. The vertically moving mechanisms 72 function to vertically move the support structure 64 between a reference position where the upper surface (support surface) of the frame support table 68 is equal in level to the upper surface of the expansion drum 66 as shown in FIG. 6A and an expansion position where the upper surface of the frame support table 68 is lower in level than the upper end of the expansion drum 66 as shown in FIG. 6B.

In performing the dividing step according to this modification, the frame 27 is first placed on the upper surface of the frame support table 68 set at the reference position and then fixed by the clamps 70 as shown in FIG. 6A. In this condition, the upper end of the expansion drum 66 is in contact with the protective member 23 in its annular area between the SAW device wafer 11 and the frame 27. Thereafter, the vertically moving mechanisms 72 are operated to lower the support structure 64 to the expansion position where the upper surface of the frame support table 68 is lower in level than the upper end of the expansion drum 66 as shown in FIG. 6B. As a result, the expansion drum 66 is relatively raised with respect to the frame support table 68, so that the protective member 23 is pushed up and expanded by the expansion drum 66. When the protective member 23 is expanded, an external force having a direction of expanding the protective member 23 is applied to the SAW device wafer 11. Accordingly, the SAW device wafer 11 (the crystal substrate 13) is divided at the modified layers 25 as a break start point to thereby obtain a plurality of SAW devices 29.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A surface acoustic wave device manufacturing method for dividing a surface acoustic wave device wafer to manufacture a plurality of surface acoustic wave devices, the surface acoustic wave device wafer including a crystal substrate having a front side partitioned into a plurality of regions by a plurality of crossing division lines, a pair of comblike electrodes formed in each region defined on the front side of the crystal substrate by the division lines, and a cover layer formed of resin for covering the whole of the front side of the crystal substrate, the surface acoustic wave device manufacturing method comprising:
a laser processed groove forming step of applying a first laser beam to the cover layer along each division line, the first laser beam having an absorption wavelength to the resin forming the cover layer, thereby forming a laser processed groove on the cover layer along each division line, the laser processed groove having a depth not reaching the crystal substrate;
a modified layer forming step of applying a second laser beam to the crystal substrate from a back side thereof along each division line after performing the laser processed groove forming step, the second laser beam having a transmission wavelength to the crystal substrate, in a condition where a focal point of the second laser beam is set inside the crystal substrate, thereby forming a modified layer inside the crystal substrate along each division line; and
a dividing step of applying an external force to the surface acoustic wave device wafer after performing the modified layer forming step, thereby dividing the surface acoustic wave device wafer along each division line to obtain the plurality of surface acoustic wave devices.

2. A surface acoustic wave device manufacturing method for dividing a surface acoustic wave device wafer to manufacture a plurality of surface acoustic wave devices, the surface acoustic wave device wafer including a crystal substrate having a front side partitioned into a plurality of regions by a plurality of crossing division lines, a pair of comblike electrodes formed in each region defined on the front side of the crystal substrate by the division lines, and a cover layer formed of resin for covering the whole of the front side of the crystal substrate, the surface acoustic wave device manufacturing method comprising:
a modified layer forming step of applying a first laser beam to the crystal substrate from a back side thereof along each division line, the first laser beam having a transmission wavelength to the crystal substrate, in a condition where a focal point of the first laser beam is set inside the crystal substrate, thereby forming a modified layer inside the crystal substrate along each division line;
a laser processed groove forming step of applying a second laser beam to the cover layer along each division line after performing the modified layer forming step, the second laser beam having an absorption wavelength to the resin forming the cover layer, thereby forming a laser processed groove on the cover layer along each division line, the laser processed groove having a depth not reaching the crystal substrate; and
a dividing step of applying an external force to the surface acoustic wave device wafer after performing the laser processed groove forming step, thereby dividing the surface acoustic wave device wafer along each division line to obtain the plurality of surface acoustic wave devices.

3. The surface acoustic wave device manufacturing method according to claim 1, wherein the cover layer includes a plurality of resin layers.
